(19) United States
(12) Patent Application Publication
(10) Pub. No.: US 2013/0252141 A1
(43) Pub. Date: Sep. 26, 2013

(54) METHOD FOR MANUFACTURING A PHOTOMASK

(71) Applicant: KOREA ADVANCED INSTITUTE OF SCIENCE AND TECHNOLOGY, (US)

(72) Inventors: Min-Yang Yang, Daejeon (KR); Bong-Chul Kang, Daejeon (KR); Jin-Ho Youn, Seoul (KR); Hu-Seung Lee, Daejeon (KR)

(73) Assignee: KOREA ADVANCED INSTITUTE OF SCIENCE AND TECHNOLOGY, Daejeon (KR)

(21) Appl. No.: 13/772,915

(22) Filed: Feb. 21, 2013

(30) Foreign Application Priority Data
Mar. 20, 2012 (KR) 10-2012-0028402

(51) Int. Cl. G03F 1/00

(52) U.S. Cl. CPC G03F 1/00
USPC 430/5

(57) ABSTRACT

In a method form manufacturing a photomask, the method includes coating an organometallic ink on a base substrate to form a solution layer. The base substrate is heat-treated on which the solution layer is formed, to self-produce a nanoparticle in the solution layer. A laser is irradiated to the solution layer, to form a metal pattern. The solution layer having the metal pattern is cleaned. The metal pattern is heat-treated. The metal pattern is covered using an encapsulant.

This application claims priority to Korean Patent Application No. 2012-28402, filed on Mar. 20, 2012, and all the benefits accruing therefrom under 35 U.S.C. §119, the contents of which in its entirety is herein incorporated by reference.

### BACKGROUND OF THE INVENTION

1. Field of the Invention

Example embodiments of the present invention relate to a method for manufacturing a photomask. More particularly, example embodiments of the present invention relate to a method for manufacturing a photomask used for photolithography.

2. Description of the Related Art

Generally, a photomask is a mask used in photolithography to form a predetermined pattern. Since a distance between adjacent wirings may be decreased and a manufacturing process may be flexible in the photolithography, the photolithography is mainly used for a patterning process both in the present and in the future. Thus, manufacturing the photomask used for the photolithography is very important.

The photomask is also manufactured through the photolithography. The manufacturing process for the photomask includes depositing a metal on a base substrate, cleaning the base substrate on which the metal is deposited, coating a photoresist, exposing the photoresist, developing the exposed photoresist, etching the metal layer, stripping the photoresist, cleaning the metal pattern formed on the base substrate, and so on.

As mentioned above, many processes are necessary to form the photomask using the photolithography, and most are processed in a vacuum state using relatively expensive equipments, so that a cost price may be increased. In addition, harmful substance may be generated in the photolithography and thus additional cleaning equipment is necessary.

### BRIEF SUMMARY OF THE INVENTION

Example embodiments of the present invention provide a method for manufacturing a photomask capable of increasing productivity and having eco-friendly processes.

In an example embodiment of a method form manufacturing a photomask according to the present invention, the method includes coating an organometallic ink on a base substrate to form a solution layer. The base substrate is heat-treated on which the solution layer is formed, to self-produce a nanoparticle in the solution layer. A laser is irradiated to the solution layer, to form a metal pattern. The solution layer having the metal pattern is cleaned. The metal pattern is heat-treated. The metal pattern is covered using an encapsulant.

In an example embodiment, the organometallic ink may be coated via one of a slot die coating, a roll coating, a blade coating, a spin coating, a spray coating and an inkjet coating.

In an example embodiment, a size of the nanoparticle may be same as or less than about 100 nm.

In an example embodiment, the base substrate may be heat-treated before the nanoparticles are combined to be a metal layer.

In an example embodiment, the base substrate may be heat-treated using one of a heat source, a heating oven, a microwave oven and a light lamp.

In an example embodiment, the nanoparticles into which the laser is irradiated may be sintered to be a metal layer, in forming the metal pattern. In addition, the laser may be irradiated in a chamber in which oxygen, humidity and light are blocked, in forming the metal pattern.

In an example embodiment, the solution layer into which the laser is not irradiated may be removed, in cleaning the solution layer, so that a transmissive portion is formed.

In an example embodiment, the metal pattern may be heat-treated using one of a heat source, a heating oven, a microwave oven and a light lamp, so that an organic material inside of the metal pattern may be evaporated and an optical density of the metal pattern is increased to enhance optical characteristics of the metal pattern and to enhance an adhesive force between the base substrate and the metal pattern.

In an example embodiment, the encapsulant may have a relatively high transmittance, and may include a high polymer film or silicon dioxide (SiO₂).

According to the example embodiments of the present invention, an organometallic ink in which a nanoparticle is self-produced through heating is used to manufacture a photomask, and thus manufacturing processes are performed in a normal state without using expensive equipments in a vacuum state, compared to a conventional manufacturing process. Thus, productivity of the photomask may be enhanced and the cost price may be decreased.

### BRIEF DESCRIPTION OF THE DRAWINGS

The above and other features and advantages of the present invention will become more apparent by describing in detailed example embodiments thereof with reference to the accompanying drawings, in which:

FIGS. 1A to 1H are processing diagrams illustrating a method for manufacturing a photomask according to an example embodiment of the present invention; and

FIG. 2 is a graph illustrating a relation between a frequency and a particle diameter.

### DETAILED DESCRIPTION OF THE INVENTION

Hereinafter, example embodiments of the present invention will be described in further detail with reference to the accompanying drawings.

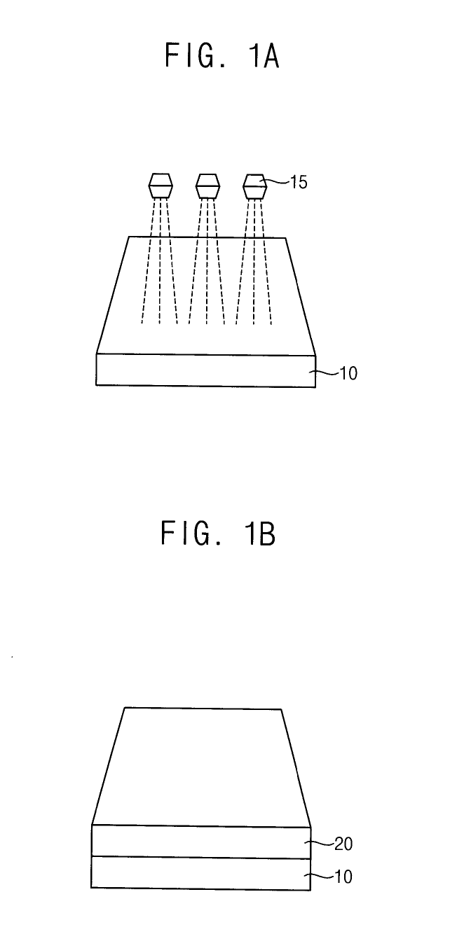

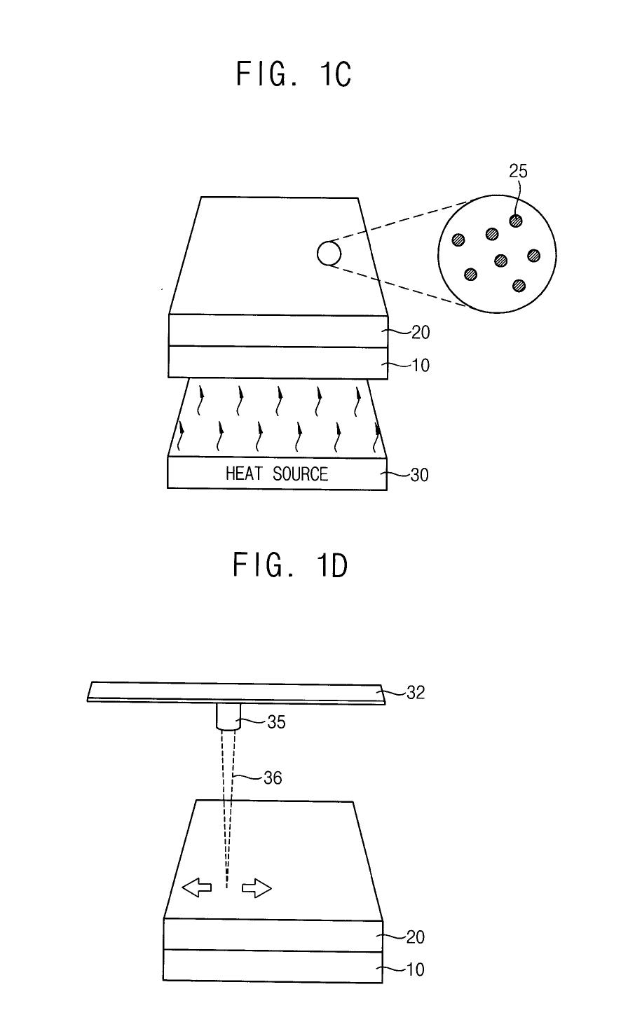

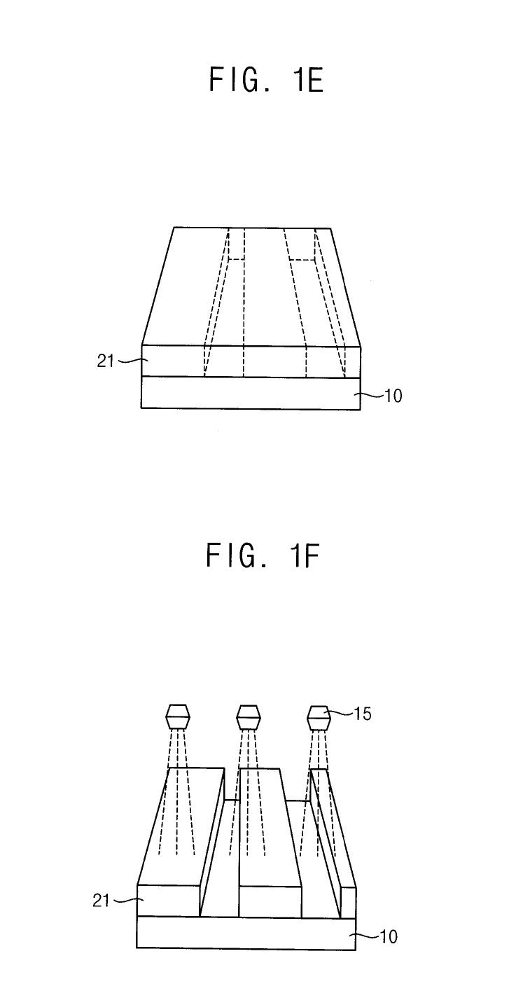

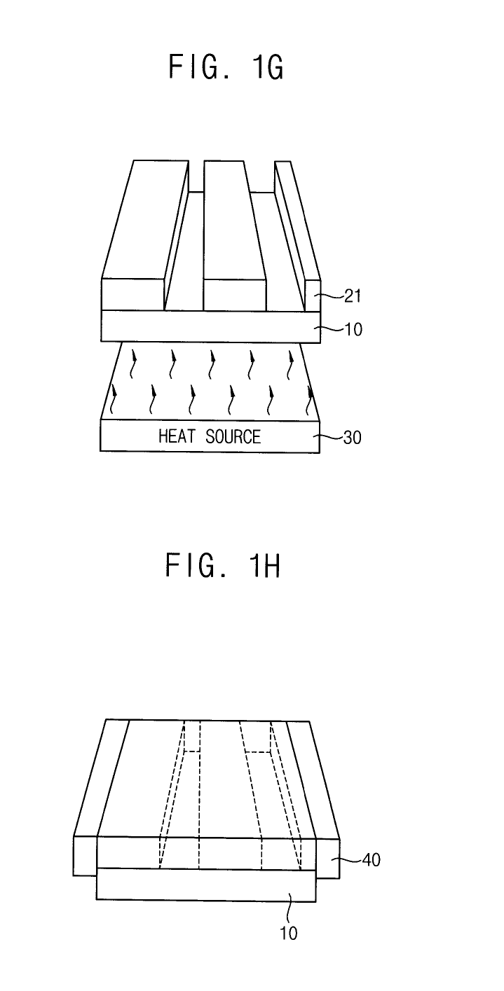

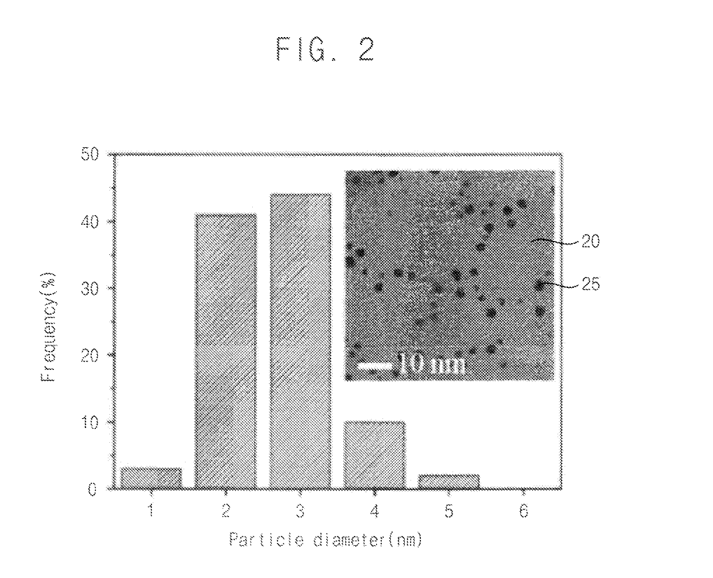

FIGS. 1A to 1H are processing diagrams illustrating a method for manufacturing a photomask according to an example embodiment of the present invention.

Referring to FIG. 1A, in manufacturing a photomask according to the present example embodiment, first, the base substrate 10 is cleaned. The base substrate 10 may include a material having a high transmittance, such as soda-lime glass, quartz and so on. A method for cleaning the base substrate 10 may include one of generating a supersonic wave to the base substrate 10 within cleaning water, injecting a liquid like cleaning water or a gas like a nitrogen gas to the base substrate 10 using a cleaning unit 15.

Referring to FIG. 1B, an organometallic ink is coated on the cleaned base substrate 10 to form a solution layer 20. In the present example embodiment, the organometallic ink coated on the base substrate 10 exists with a transparent liquid state like an ink at a room temperature, and includes a metallic ion such as gold (Au), silver (Ag), copper (Cu) and so on, and an organic material combined with each other. The organometallic ink does not include a metallic ion with a solid state, and thus is transparent at a room temperature. However, when a heat is applied to the organometallic ink from outside, the combination of the metallic ion and the organic material is broke down to be deoxidized, and thus a nano-sized metallic particle with the solid state is educed. In the present example embodiment, the organometallic ink having above-mentioned characteristics is used to manufacture the photomask.

In addition, the metal included in the organometallic ink may be all kinds of metals which may be combined with the organic material to exist with a liquid state at the room temperature, in addition to gold, silver and copper.

A method of coating the organometallic ink on the base substrate 10 includes slot die coating, roll coating, blade coating, spin coating, spray coating, inkjet coating and so on.

Referring to FIG. 1C, the base substrate 10 on which the solution layer 20 is formed is pre-baked. Here, as for a method for heat-treating the base substrate 10, as illustrate in FIG. 1C, a heat source 30 is disposed under the base substrate 10 and applies the heat to the base substrate 10. Alternatively, although not shown in figure, the heat source may be disposed adjacent to the base substrate 10 to apply the heat to the base substrate 10. In addition, the base substrate 10 on which the solution layer 20 is formed may be disposed in a heating chamber such as a heating oven, a microwave oven and so on to apply the heat to the base substrate 10. Further, a light lamp may be disposed over or under the base substrate 10 to apply the heat to the base substrate 10.

Accordingly, when the heat is applied to the solution layer 20, a nanoparticle 25 is self-produced inside of the solution layer 20 formed by the organometallic ink. Here, the self-production of the nanoparticle means that the combination between the metallic ion and the organic material inside of the organometallic ink is broke down to be deoxidized so that a nano-sized metallic particle with the solid state is educed. The self-production of the nanoparticle is proportionate to a temperature of the heat, and the educed nanoparticles 25 are combined to be a metal layer.

In the present example embodiment, when the metal layer starts to be formed, a metal pattern is hard to be formed using a laser. Thus, a temperature of the heat applied to the solution layer 20 through the heat source 30 should be limited under the temperature at which the nanoparticles start to be combined with each other to form the metal layer. For example, the temperature is between a minimum temperature at which the nanoparticle 25 starts to be self-produced in the organometallic ink and a maximum temperature at which the nanoparticles 25 start to be combined with each other.

Referring to FIG. 1D, a laser 36 is irradiated to the solution layer 20 in which the nanoparticle 25 is self-produced. For example, the laser 36 is generated from a laser generator 35 and a scanner 32 makes a predetermined pattern, and then the laser having the predetermined pattern is irradiated to the solution layer 20. Alternatively, although not shown in the figure, the laser 36 is generated from the laser generator 35, and a stage on which the base substrate 10 is disposed moves with a predetermined pattern, and then the laser having the predetermined pattern is relatively irradiated to the solution layer 20. Further, although not shown in the figure, the laser 36 is generated from the laser generator 35, and the scanner and the stage relatively move with a predetermined pattern at the same time, and then the laser having the predetermined pattern is irradiated to the solution layer 20.

Here, a light and heat chemical reaction occurs in the solution layer 20 into which the laser 36 is irradiated, and thus the self-produced nanoparticles 25 are sintered with each other to form a nano metal layer. For example, the solution layer 20 into which the laser 36 is irradiated is not removed via a cleaning process, and remains on the base substrate 10. Thus, a light blocking portion may be formed.

Referring to FIG. 1E, when the laser 36 is irradiated to the solution layer 20, the nanoparticles 25 are sintered with each other to be the nano metal layer at a portion of the solution layer 20 into which the laser 36 is irradiated, and thus a predetermined metal pattern 21 is formed.

For example, in the laser irradiating process as illustrated in FIGS. 1D and 1E, the laser is absorbed by the solution layer 20, and a portion of the solution layer 20 absorbing the laser is sintered to be the metal pattern 21. For example, the solution layer 20 may be the organometallic ink, and thus nano particles may be generated and the nano particles may be sintered to be the metal pattern 21 in the portion of the solution layer 20 absorbing the laser.

The laser irradiation process may be formed in a chamber (not shown) in which oxygen, humidity and light are blocked. For example, the chamber is in a vacuum state, nitrogen or argon filled state, or a darkroom state, and thus the oxygen, the humidity and the light may be completely blocked.

Thus, the metal pattern 21 formed via the laser irradiation process may have increased uniformity or quality.

Accordingly, the solution layer 20 into which the laser 36 is irradiated remains and the light passes through the solution layer 20 into which the laser 36 is not irradiated, so that the laser 36 is irradiated to form a pattern reversely considering a final pattern formed through the photomask which is manufactured via the method according to the present example embodiment.

Referring to FIG. 1F, the solution layer 20 into which the laser 36 is not irradiated. is cleaned. Thus, a portion of the solution layer 20 at which the nano metal layer is not formed and which the light passes through, is removed. Thus, the solution layer 20 is formed as a metal pattern 21 having a predetermined pattern, and the organometallic ink coated on the base substrate into which the laser 36 is not irradiated is totally removed.

In addition, the base substrate 10 and the solution layer 20 are both cleaned using the cleaning unit 15, and thus foreign substance formed on the base substrate 10 or the solution layer 20 is cleanly removed.

Referring to FIG. 1G, the base substrate 10 and the metal pattern 21 formed on the base substrate 10 are heat-treated. Here, as for the method of the heat-treatment, as mentioned referring to FIG. 1G, a heat source 30 is disposed under the base substrate 10, and the heat is applied to the base substrate 10. Alternatively, although not shown in figure, the heat source may be disposed adjacent to the base substrate 10 to apply the heat to the base substrate 10. In addition, the base substrate 10 on which the solution layer 20 is formed may be disposed in a heating chamber such as a heating oven, a microwave oven and so on to apply the heat to the base substrate 10. Further, a light lamp may be disposed over or under the base substrate 10 to apply the heat to the base substrate 10.

Accordingly, the heat source 30 applies the heat, so that the organic material inside of the metal pattern 21 may be evaporated and the nano metal layer inside of the metal pattern 21 may be more densified. In addition, an optical density of the metal pattern is increased to enhance optical characteristics of the metal pattern and to enhance an adhesive force between the base substrate and the metal pattern. For example, a transmissivity of the metal pattern may be decreased. The metal pattern 21 formed as mentioned above may be used as a photomask. Here, the metal pattern 21 may be a light blocking portion blocking a light when used as the photomask, and a portion at which the metal pattern 21 is not formed may be a light transmissive portion transmitting the light.

Referring to FIG. 1H, the metal pattern 21 is covered by an encapsulant 40. The encapsulant 40 covers all of the metal pattern 21 as illustrated, and may partially cover the base substrate 40. Alternatively, the encapsulant 40 covers all of the metal pattern 21 and the base substrate 40.

For example, the encapsulant 40 may have a relatively high transmittance, and may include a pellicle having a high polymer film or silicon dioxide (SiO₂). The encapsulant 40 has high transparency and relatively harder material, to increase durability of the photomask and to prevent the photomask from be oxidized due to oxygen or humidity of an atmosphere. A thickness of the encapsulant 40 may be about several hundred nanometers.

FIG. 2 is a graph illustrating a relation between a frequency and a particle diameter. When the heat is applied to the solution layer 20 and the nanoparticle 25 is self-produced inside of the solution layer 20 including the organometallic ink, a frequency of the self-production of the nanoparticle 25 is illustrated in FIG. 2.

Referring to FIG. 2, when the temperature of the heat from the heat source 30 is between a first temperature at which the nanoparticle 25 starts to be self-produced in the solution layer 20 and a second temperature at which the nanoparticles 25 are sintered with each other, the nanoparticles 25 having a diameter substantially same as or less than about 100 nm occupies substantially same or more than about 80% in the solution layer 20 including the organometallic ink. For example, most of the nanoparticles 25 self-produced in the solution layer 20 may be between about 2 nm and about 3 nm.

According to the example embodiments, an organometallic ink in which a nanoparticle is self-produced through heating is used to manufacture a photomask, and thus manufacturing processes are performed in a normal state without using expensive equipments in a vacuum state, compared to a conventional manufacturing process. Thus, productivity of the photomask may be enhanced and the cost price may be decreased.

The foregoing is illustrative of the present invention and is not to be construed as limiting thereof. Although a few example embodiments of the present invention have been described, those skilled in the art will readily appreciate that many modifications are possible in the example embodiments without materially departing from the novel teachings and advantages of the present invention. Accordingly, all such modifications are intended to be included within the scope of the present invention as defined in the claims. In the claims, means-plus-function clauses are intended to cover the structures described herein as performing the recited function and not only structural equivalents but also equivalent structures. Therefore, it is to be understood that the foregoing is illustrative of the present invention and is not to be construed as limited to the specific example embodiments disclosed, and that modifies to the disclosed example embodiments, as well as other example embodiments, are intended to be included within the scope of the appended claims. The present invention is defined by the following claims, with equivalents of the claims to be included therein.

What is claimed is:

1. A method for manufacturing a photomask, the method comprising:
coating an organometallic ink on a base substrate, to form a solution layer;
heat-treating the base substrate on which the solution layer is formed, to self-produce a nanoparticle in the solution layer;
irradiating a laser to the solution layer, to form a metal pattern;
cleaning the solution layer having the metal pattern;
heat-treating the metal pattern; and
covering the metal pattern using an encapsulant.

2. The method of claim 1, wherein the organometallic ink is coated via one of a slot die coating, a roll coating, a blade coating, a spin coating, a spray coating and an inkjet coating.

3. The method of claim 1, wherein a size of the nanoparticle is same as or less than about 100 nm.

4. The method of claim 1, wherein the base substrate is heat-treated before the nanoparticles are combined to be a metal layer.

5. The method of claim 4, wherein the base substrate is heat-treated using one of a heat source, a heating oven, a microwave oven and a light lamp.

6. The method of claim 1, wherein the nanoparticles into which the laser is irradiated are sintered to be a metal layer, in forming the metal pattern.

7. The method of claim 6, wherein the laser is irradiated in a chamber in which oxygen, humidity and light are blocked, in forming the metal pattern.

8. The method of claim 1, wherein the solution layer into which the laser is not irradiated is removed, in cleaning the solution layer, so that a transmissive portion is formed.

9. The method of claim 1, wherein the metal pattern is heat-treated using one of a heat source, a heating oven, a microwave oven and a light lamp, so that an organic material inside of the metal pattern is evaporated and an optical density of the metal pattern is increased to enhance optical characteristics of the metal pattern and to enhance an adhesive force between the base substrate and the metal pattern.

10. The method of claim 1, wherein the encapsulant has a relatively high transmittance, and comprises a high polymer film or silicon dioxide (SiO₂).
